(19) United States
(12) Patent Application Publication
(10) Pub. No.: US 2024/0339974 A1
(43) Pub. Date: Oct. 10, 2024

(54) VARACTOR TUNED INPUT TRAP

(71) Applicant: SKYWORKS SOLUTIONS, INC., Irvine, CA (US)

(72) Inventor: Philip John LEHTOLA, Cedar Rapids, IA (US)

(21) Appl. No.: 18/627,682

(22) Filed: Apr. 5, 2024

Related U.S. Application Data
(60) Provisional application No. 63/458,104, filed on Apr. 8, 2023.

(51) Int. Cl. H03F 3/24; H03J 3/18; H03J 5/24

(52) U.S. Cl. CPC H03F 3/245; H03J 3/185; H03J 5/244; H03F 2200/451

(57) ABSTRACT

A power amplifier can include an input stage that includes a first amplifying transistor having an input node and an output node, such that a signal at the input node has a first power level and an amplified signal at the output node has a second power level. The power amplifier can further include a second stage implemented relative to the output node that includes a second amplifying transistor, and an adjustable frequency resonant circuit implemented relative to an input of the second stage, configured to store energy of the amplified signal at the second power level.

### CROSS-REFERENCE TO RELATED APPLICATION(S)

This application claims priority to U.S. Provisional Application No. 63/458,104 filed Apr. 8, 2023, entitled VARACTOR TUNED INPUT TRAP. The content of the above-referenced application is hereby expressly incorporated by reference herein in its entirety for all purposes.

### BACKGROUND

### Field

The present disclosure relates to power amplification of signals such as radio-frequency (RF) signals.

### Description of the Related Art

In many radio-frequency (RF) applications, it is desirable to amplify a signal. In an example context of a transmit operation, such amplification of signal can provide power amplification of the signal, and the power-amplified signal can be transmitted from an RF device such as a wireless device.

### SUMMARY

In accordance with some implementations, the present disclosure relates to a power amplifier that includes an input stage that includes a first amplifying transistor having an input node and an output node, such that a signal at the input node has a first power level and an amplified signal at the output node has a second power level. The power amplifier further includes a second stage implemented relative to the output node that includes a second amplifying transistor, and an adjustable frequency resonant circuit implemented relative to an input of the second stage, configured to store energy of the amplified signal at the second power level.

In some embodiments, the adjustable frequency resonant circuit can comprise a series LC tank circuit with an adjustable capacitance for tuning a resonant frequency of the series LC tank circuit. In some embodiments, the power amplifier can include an adjustable control voltage configured to set or adjust the adjustable capacitance of the series LC tank circuit. In some embodiments, the adjustable frequency resonant circuit is configured to store energy of the amplified signal relative to a resonant frequency of the adjustable frequency resonant circuit. In some embodiments, the resonant frequency can correspond to a desired transmission signal frequency. In some embodiments, the resonant frequency can be adjustable in response to a change in the desired transmission signal frequency.

In some embodiments, the adjustable frequency resonant circuit can comprise a varactor in series with an inductance. In some embodiments, the adjustable frequency resonant circuit can comprise a harmonic trap with an adjustable resonant frequency. In some embodiments, the resonant frequency of the adjustable frequency resonant circuit can be adjusted by adjusting a capacitance of the varactor.

In some embodiments, the capacitance of the varactor can be controlled via an adjustable control voltage or an adjustable control current. In some embodiments, a value of the adjustable control voltage or a value of the adjustable control current can be adjusted in response to a change in a desired transmission signal frequency.

In some embodiments, the varactor can comprise two reverse-biased Schottky diodes arranged cathode to cathode, with a control voltage inserted at a node between the cathodes. In some embodiments, the control voltage can be arranged to set or adjust a capacitance of the varactor. In some embodiments, the varactor further comprises a capacitance electrically coupled in parallel with the two reverse-biased Schottky diodes. In some embodiments, the varactor can comprise a resistance electrically coupled in parallel with the two reverse-biased Schottky diodes.

In some embodiments, the inductance is electrically coupled to ground. In some embodiments, the adjustable frequency resonant circuit can include a capacitance in series with the varactor and the inductance.

In some embodiments, a resonant frequency of the adjustable frequency resonant circuit can be configured to be selectable from a range of frequency values in response to a frequency of the signal at the input node.

In some embodiments, the second stage can include a third amplifying transistor arranged in cascode configuration with the second amplifying transistor.

In some embodiments, the adjustable frequency resonant circuit can include a variable capacitance circuit configured to provide a variable capacitance value based on a desired resonance frequency. In some embodiments, the variable capacitance circuit can be configured to provide a plurality of discrete values based on the desired resonance frequency. In some embodiments, the variable capacitance circuit can include a plurality of capacitances arranged to be electrically parallel, and at least one of the plurality of capacitances can be configured to be switchable.

In some embodiments, the variable capacitance circuit can be configured to provide analog values based on the desired resonance frequency. In some embodiments, the variable capacitance circuit can include a diode capacitance circuit controlled by a control signal that depends on the desired resonance frequency. In some embodiments, the variable capacitance circuit can include a plurality of diodes controlled by a control voltage to provide the variable capacitance value based on the desired resonance frequency. In some embodiments, the control voltage being provided to the variable capacitance circuit depends on the desired resonance frequency.

In some embodiments, the plurality of diodes includes a first diode and a second diode arranged such that an anode of the first diode is on an input side of the variable capacitance circuit, and anode of the second diode is on an output side of the variable capacitance circuit, and cathodes of the first and second diodes are coupled to each other, and the control voltage is provided to a node between the cathodes of the first and second diodes.

In accordance with some implementations, the present disclosure relates to a semiconductor die comprising a substrate and a power amplifier implemented on the substrate. The power amplifier includes an input stage that includes an amplifying transistor having an input node and an output node, such that a signal at the input node has a first power level and an amplified signal at the output node has a second power level. The power amplifier further includes a second stage implemented relative to the output node that includes a second amplifying transistor. The power amplifier further includes an adjustable frequency resonant circuit implemented relative to an input of the second stage, configured to store energy of the amplified signal at the second power level.

In some embodiments, the adjustable frequency resonant circuit can be configured to store energy of the amplified signal relative to a resonant frequency of the adjustable frequency resonant circuit. In some embodiments, the resonant frequency can correspond to a desired transmission signal frequency. In some embodiments, the resonant frequency can be adjustable in response to a change in the desired transmission signal frequency.

In some embodiments, the adjustable frequency resonant circuit comprises a varactor in series with an inductance, and a resonant frequency of the adjustable frequency resonant circuit can be adjusted by adjusting a capacitance of the varactor.

In accordance with some implementations, the present disclosure relates to a packaged module comprising a packaging substrate and a semiconductor die mounted on the packaging substrate and including a power amplifier implemented on the semiconductor die. The power amplifier includes an input stage that includes an amplifying transistor having an input node and an output node, such that a signal at the input node has a first power level and an amplified signal at the output node has a second power level. The power amplifier further includes a second stage implemented relative to the output node that includes a second amplifying transistor. The power amplifier further includes an adjustable frequency resonant circuit implemented relative to an input of the second stage, configured to store energy of the amplified signal at the second power level.

In accordance with some implementations, the present disclosure relates to a wireless device comprising an antenna configured to receive a signal, an amplifier assembly in communication with the antenna and configured to amplify the signal, and a transceiver in communication with the amplifier assembly and configured to process the amplified signal. The amplifier assembly includes a power amplifier, including an input stage that includes an amplifying transistor having an input node and an output node, such that a signal at the input node has a first power level and an amplified signal at the output node has a second power level, and a second stage implemented relative to the output node that includes a second amplifying transistor. The power amplifier further includes an adjustable frequency resonant circuit implemented relative to an input of the second stage, configured to store energy of the amplified signal at the second power level.

In some embodiments, the wireless device can be a cellular phone configured to operate in one or more cellular bands.

In some embodiments, the adjustable frequency resonant circuit can be configured to store energy of the amplified signal relative to a resonant frequency of the adjustable frequency resonant circuit. In some embodiments, the resonant frequency corresponds to a desired transmission signal frequency, and the resonant frequency can be adjustable in response to a change in the desired transmission signal frequency.

In some embodiments, the adjustable frequency resonant circuit comprises a varactor and an inductance, and the resonant frequency of the adjustable frequency resonant circuit can be adjusted by adjusting a capacitance of the varactor.

### BRIEF DESCRIPTION OF THE DRAWINGS

FIG. 1 depicts a block diagram of a radio-frequency (RF) module having a power amplifier that includes and/or can be coupled to a resonant circuit.

FIG. 2 shows an example of a power amplifier that can include and/or be provided with a resonant circuit along an input path of a transistor.

FIG. 3 shows that in some embodiments, the power amplifier of FIG. 2 can be implemented on a substrate.

FIG. 4 shows an example of a variable capacitance circuit that can be utilized to form a variable-tuned resonant circuit in each of the example power amplifiers of FIGS. 2 and 3.

FIG. 5 shows an example relationship between a capacitance of the variable capacitance circuit of FIG. 4 and an effective series resistance of the variable capacitance circuit.

FIG. 6 shows examples of gain and linearity plots, and how such parameters can vary with a control voltage applied to the variable capacitance circuit.

FIG. 7 shows that in some embodiments, the power amplifier of FIG. 2 can include a variable-tuned harmonic trap circuit implemented along an interstage path.

FIG. 8 shows that in some embodiments, the power amplifier of FIG. 7 can be implemented on a substrate of a die.

FIGS. 9A and 9B show examples of variable capacitance circuits that can be utilized to form a variable-tuned resonant circuit in the example power amplifier of FIG. 7.

FIG. 10 shows that in some embodiments, a semiconductor die can include one or more amplifiers as described herein.

FIG. 11 shows that in some embodiments, one or more features as described herein can be implemented in a packaged module.

FIG. 12 depicts an example wireless device having one or more advantageous features described herein.

### DETAILED DESCRIPTION OF SOME EMBODIMENTS

The headings provided herein, if any, are for convenience only and do not necessarily affect the scope or meaning of the claimed invention.

In many applications, such as in radio-frequency (RF) applications, an amplifier such as a power amplifier (PA) is implemented in a semiconductor die, and such a die is often mounted on a module such as a power amplifier module (PAM) or a front end module (FEM). A perfect or ideal amplifier has linear gain (AMAM) and phase (AMPM) characteristics versus output power (i.e. Gain slope=0 dB/dB and Phase slope=0 deg/dB). However, achieving a linear gain and phase characteristic while maintaining output power and efficiency is a key challenge in practical power amplifier design.

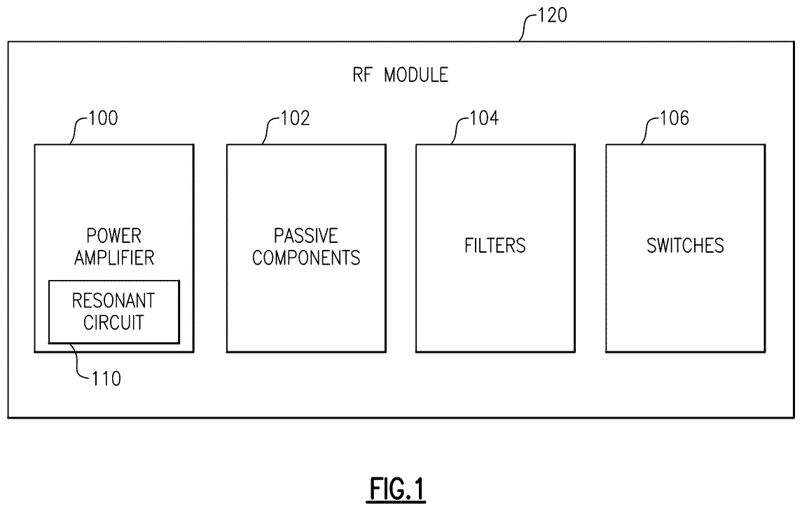

FIG. 1 depicts a block diagram of a radio-frequency (RF) module 120 that includes a power amplifier 100. In some embodiments, such a power amplifier 100 can include and/or be coupled to a resonant circuit 110 having one or more features as described herein. Examples of such a resonant circuit 110 are described herein in greater detail.

As shown in FIG. 1, the RF module 120 can further include one or more passive components 102, one or more filters 104, and one or more switches 106. As described herein, some or all of such components can impact the output power and efficiency of the module 120 during operation of the module 120. Further, some or all of such components can, in combination with the components of the power amplifier 100, result in a change in gain (e.g., decrease in gain) of the power amplifier 100.

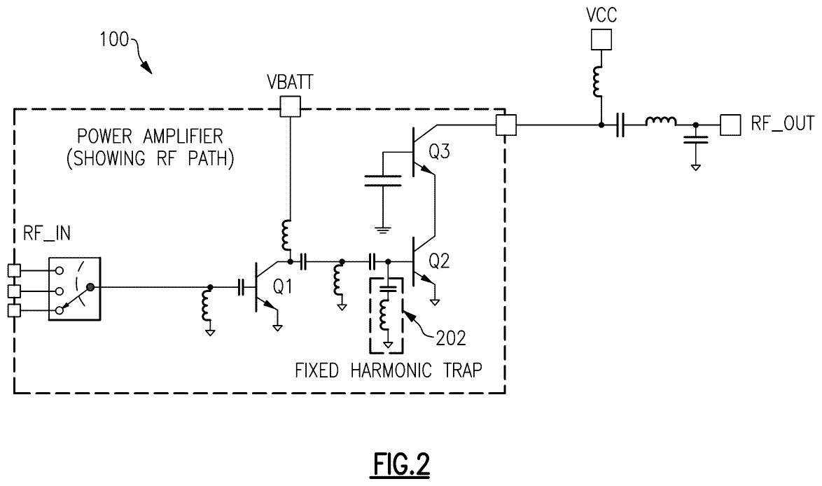

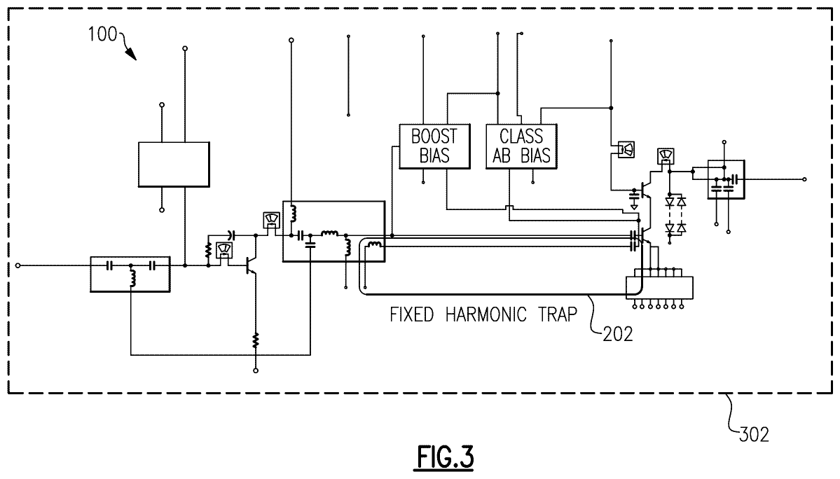

Class AB amplifiers with Class F load terminations can be used in the power amplifiers of mobile handsets, for example, for achieving high efficiency and a near linear gain and phase characteristic. Referring to FIG. 2, in some situations, AMPM performance of the amplifier 100 can be improved by placing a low impedance resonant circuit 202, such as the series LC circuit 202 shown at FIG. 2, at a selected location within the power amplifier 100. An example implementation of the power amplifier 100 circuit of FIG. 2 that may be formed on a substrate 302 of a die 300 is shown at FIG. 3, including example components. In an example, the LC circuit 202 may be tuned to the 2nd harmonic of the chosen radio frequency as a fixed 2nd harmonic trap.

FIG. 2 shows an example of a power amplifier 100 that can include and/or be provided with a resonant circuit (110 in FIG. 1), such as the LC circuit 202 shown. The example power amplifier 100 is shown to have an input node RF_in for receiving a signal to be amplified and an output node RF_out for accessing the amplified signal. A power amplifier 100 can be configured for a single input signal or configured to receive and select multiple input signals. The example power amplifier 100 of FIG. 2 shows a multi-band input, where one of multiple radio frequency (RF) inputs can be selected. One of the multiple input paths is shown at FIG. 3 for clarity.

The input node RF_in is shown to be coupled through an input path to an input of an amplifying transistor Q1 of a first stage. A partially amplified signal from an output of Q1 is shown to be coupled through an interstage path to an input of an amplifying transistor Q2 of a second stage. The transistor Q2 is shown to be coupled to another amplifying transistor Q3 in a cascode configuration, such that an output of the transistor Q3 is coupled to the output node RF_out of the power amplifier 100.

In the example of FIG. 2, each of the amplifiers Q1, Q2, Q3 is shown to be implemented as a bipolar-junction transistor having a base, an emitter and a collector. Thus, Q1 is shown to have its base as an input, its collector as an output, and its emitter coupled to ground. Q2 is shown to be implemented as common emitter device coupled to Q3, which is implemented as a common base device. Thus, Q2 has its base as an input (coupled to the output of Q1), its collector as an output, and its emitter coupled to ground. Q3 has its emitter as an input (coupled to the output (collector) of Q2), its collector as an output (coupled to the power amplifier output RF_OUT), and its base coupled to ground through a capacitance.

In the example of FIG. 2, the transistor Q1 is shown to be provided with a supply voltage VBATT to its collector through a choke inductance. It will be understood that Q3 is shown to be provided with a supply voltage VCC through its collector via another inductance. The voltage of VBATT and VCC may or may not be the same. Also, it will be understood that each of the transistors Q1, Q2, Q3 may be provided with a bias signal, if desired.

It will be understood in the example of FIG. 2 that an input LC filter as shown, or alternatively an input matching circuit, can be provided at the base of the input transistor Q1. Similarly, an interstage matching circuit (or alternatively a filter) can be provided at the base of transistor Q2, as shown. The matching circuit comprises a T-circuit having two capacitances in series, and an inductance that couples a node between the capacitances to ground. Capacitance values of the two capacitances may or may not be the same. It will be understood that a power amplifier 100 having one or more features as described herein may or may not have matching circuits, and that such matching circuit(s) can also be implemented in other forms (e.g., other than a T-circuit). Alternatively, a tank circuit or a filter may be used at either or both of these locations (or other locations), which may be implemented in any form desired.

Referring to FIG. 2, it will be understood that in some embodiments, a resonant circuit 202 (resonant circuit 110 at FIG. 1) can be implemented at one or more locations within the power amplifier 100. For example, as shown, a resonant circuit 202 can be implemented along the input path of the second stage transistor Q2 (e.g., after the output of Q1 and between the interstage matching circuit and the input of Q2). In other examples, a resonant circuit 202 can be implemented at other portions of the amplifier circuit 100, such as along the input path to transistor Q1 for example.

However, the resonant circuit 202 (i.e., series LC circuit) at the input of the second stage of the power amplifier 100 also acts as a band-pass filter. It is generally desirable to achieve broad band performance out of a power amplifier 100 for a mobile handset. Placing a fixed harmonic trap at the input of the second stage of the amplifier 100 inherently narrows the available band at that point in the amplifier 100. For example, the fixed harmonic trap 202 may be resonant at the 2nd harmonic of a designed frequency, optimizing performance at the middle of the band while trading performance (e.g., having reduced performance) at the rest of the desired band. The resonant frequency of the fixed harmonic trap 202 is selected and optimized by disposing (e.g., forming, placing, etc.) fixed-value inductors and capacitors with desired values within the circuit on the substrate 302 of the die 300, as shown at FIG. 3. This results in a power amplifier designed for a narrow bandwidth.

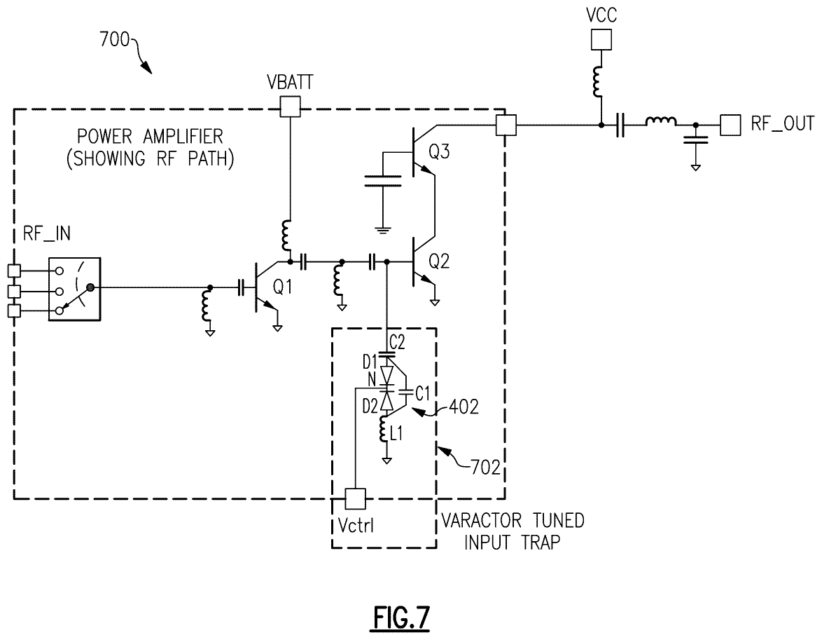

In various embodiments, a solution that provides for optimized amplifier performance without sacrificing broadband capability is disclosed herein. The solution includes a variable-tuned harmonic trap circuit (“varactor tuned input trap”) 702 (see FIG. 7) that can be disposed at one or more locations of the power amplifier 100 circuit to achieve high efficiency and an optimized linear gain and phase characteristic of the amplifier 100. The variable-tuned harmonic trap circuit 702 includes the capability to adjust the resonant frequency of the harmonic trap circuit, to optimize the AMPM of the power amplifier 100 around a frequency desired to be transmitted. As the desired transmission frequency is changed, the resonant frequency of the variable-tuned harmonic trap circuit 702 may be adjusted to conform to the new transmission frequency and maintain optimum performance.

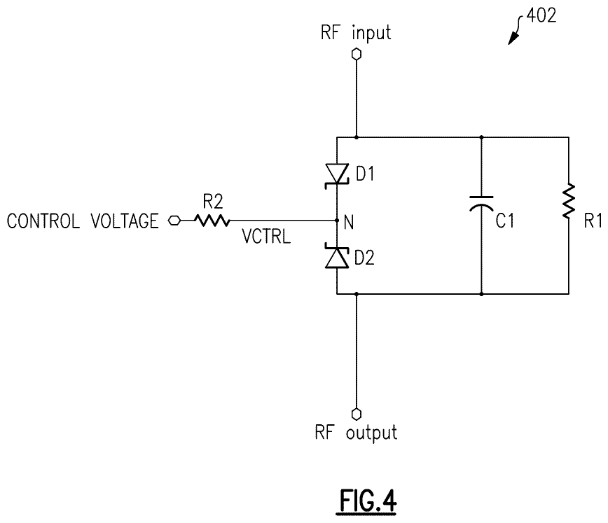

In an embodiment, the variable-tuned harmonic trap circuit 702 includes a variable capacitance circuit (or “varactor”) 402, as shown at FIG. 4. In the embodiment, the variable-tuned harmonic trap circuit 702 can be tuned (or the resonant frequency can be adjusted) by tuning (or adjusting) the capacitance value of the varactor 402. In some examples, the varactor 402 can be used with one or more fixed inductors or adjustable inductor(s) to form the variable-tuned harmonic trap circuit 702. For example, the varactor 402 can be placed in series with an inductance to form the variable-tuned harmonic trap circuit 702.

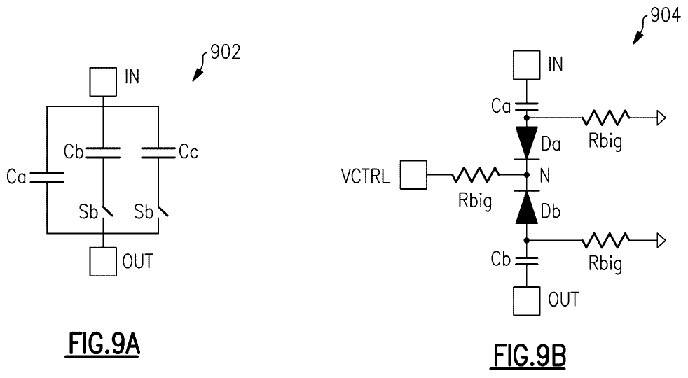

FIG. 4 shows an example of a varactor circuit 402 that can be used to form the variable-tuned harmonic trap circuit 702 for a power amplifier such as the power amplifier 100 of FIGS. 2 and 3. The variable-tuned harmonic trap circuit 702 can replace the fixed harmonic trap circuit 202 to provide the desired optimized performance and broad bandwidth capability for the power amplifier 100 (or a power amplifier of different design). It will be understood that the variable-tuned harmonic trap circuit 702 (as shown at FIG. 7) can also be implemented with different configurations of a varactor circuit than the example of FIG. 4 (some examples are shown at FIGS. 9A and 9B).

In the example shown at FIG. 4, the varactor 402 is formed using two reverse-biased Schottky diodes (D1 and D2) arranged in an anti-parallel connection. For example, the Schottky diodes D1 and D2 are arranged cathode to cathode, with a node “n” between the cathodes. A control voltage (VCTRL) is inserted at the node n, via an impedance R2. In other words, a control current can be used with the impedance R2 to form the control voltage VCTRL. The value of the control current or resulting control voltage VCTRL determines the capacitance of the varactor 402. As shown at FIG. 4, the input of the varactor 402 is at the anode of D1 and the output of the varactor 402 is at the anode of D2. One or more capacitances C1 and one or more resistances R1 are disposed in parallel with the pair of diodes D1 and D2, spanning from the anode of D1 to the anode of D2. In some cases, disposing the capacitance(s) C1 in parallel with the diodes D1 and D2 increases the overall capacitance of the varactor 402 and disposing the resistance(s) R1 in parallel with the diodes D1 and D2 reduces the overall impedance of the varactor 402. Thus, a low impedance trap circuit 702 can be achieved as desired.

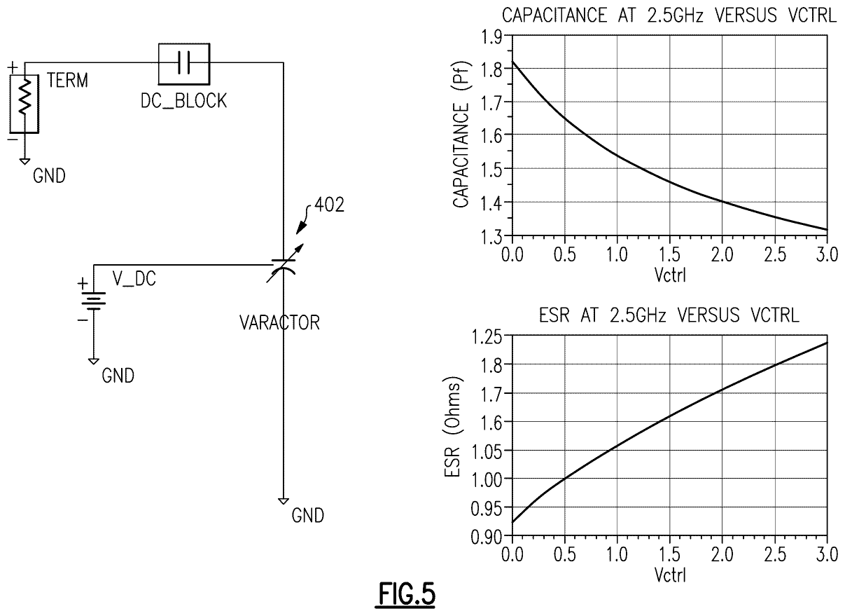

The capacitance of the varactor 402 is adjusted by adjusting the control voltage VCTRL. Referring to FIG. 5, in an example, the capacitance of the varactor 402 is a maximum when the control voltage VCTRL is at 0 volts. As the control voltage VCTRL increases, the capacitance of the varactor 402 decreases and the effective series resistance (ESR) increases. Accordingly, the resonant frequency of the variable-tuned harmonic trap circuit 702 (see FIG. 7) is adjusted by adjusting the capacitance of the varactor 402, via adjusting the control voltage VCTRL. In other words, the resonant frequency of the variable-tuned harmonic trap circuit 702 is dependent on the capacitance of the varactor 402 and can be adjusted by adjusting the capacitance of the varactor 402.

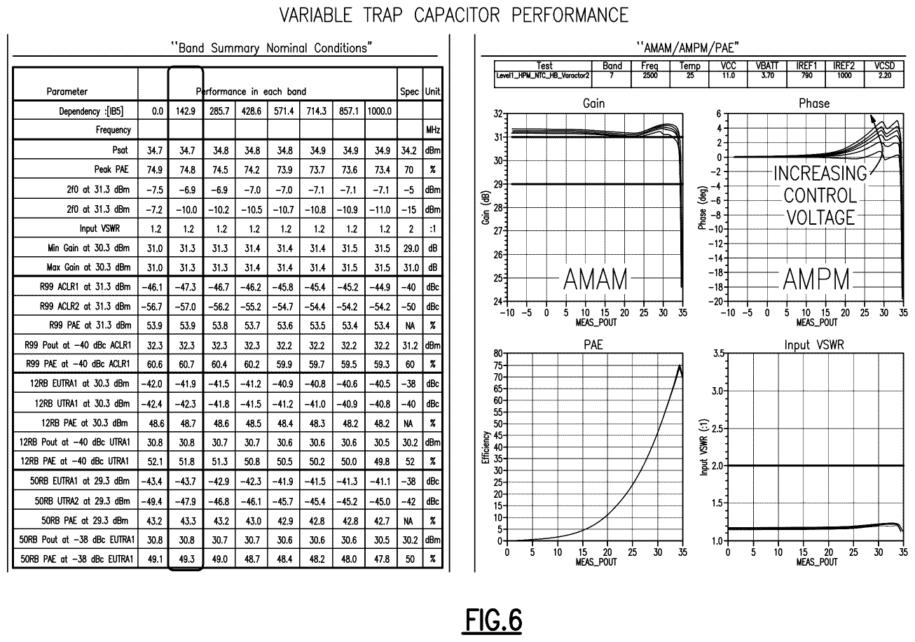

Referring to FIG. 6, example performance characteristics are shown in the provided charts and graphs. For example, a plot of the gain of the amplifier 100 versus the control voltage (“meas_pout”), which reflects the capacitance of the varactor 402 and the resonant frequency of the variable-tuned input trap 702 is shown in the “AMAM” graph. As can be seen, the gain is nearly linear across a broad range of control voltage values (e.g., from −10 VDC to 35 VDC). Also, a plot of the phase change (in degrees) versus the control voltage (“meas_pout”) is shown in the “AMPM” graph. The phase is constant (i.e., without a significant shift) from −10 VDC to 10 VDC. A slight phase shift of approximately +1 degree is seen at approximately 20 VDC, and no more than about +5 degrees phase shift is seen when approaching 35 VDC. Another graph at FIG. 6 shows the efficiency of the amplifier 100 versus the control voltage (“meas_pout”), which steadily increases to about 75% near 35 VDC. A further graph shows the input voltage standing wave ratio (VSWR) versus the control voltage (“meas_pout”), which is nearly flat at about 1.2:1 over the range of control voltage values (e.g., from OVDC to 35 VDC). These graphs show that the AMPM of the power amplifier 100 can be optimized using the varactor tuned input trap 702 and without replacing physical inductors or capacitors on the die. In other words, high efficiency and a near linear gain and phase characteristic can be achieved using the varactor tuned input trap 702 with the variable-capacitance varactor 402.

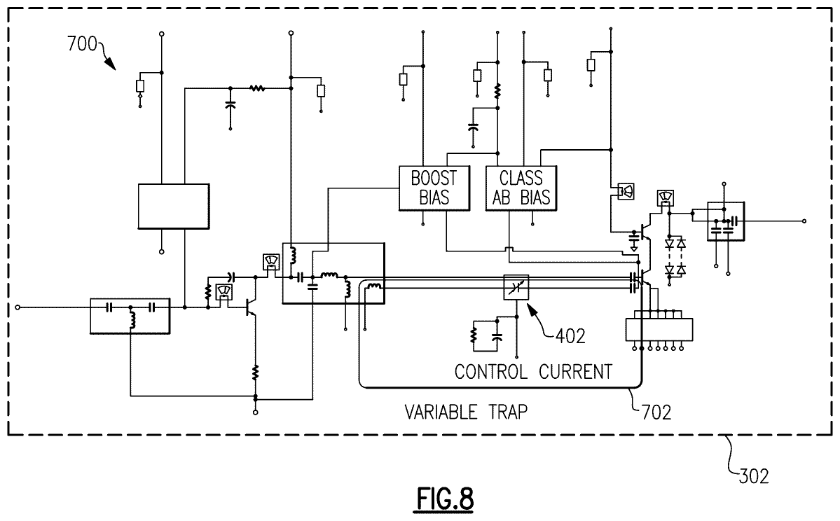

FIG. 7 shows an example of a power amplifier 700 that includes a varactor tuned input trap 702. An example implementation of the power amplifier 700 circuit of FIG. 7 that may be formed on a substrate 302 of a die 300 is shown at FIG. 8, including example components. The location of the varactor tuned input trap 702 in the examples of FIG. 7 and FIG. 8 shows one possible location, and other locations within the amplifier 700 are possible. As discussed with reference to FIG. 2, the example power amplifier 700 is shown to include an input node RF_in for receiving a signal to be amplified and an output node RF_out for accessing the amplified signal. A power amplifier 700 can be configured for a single input signal or configured to receive and select multiple input signals. The example power amplifier 700 of FIG. 7 shows a multi-band input, where one of multiple radio frequency (RF) inputs can be selected. One of the multiple input paths is shown at FIG. 8 for clarity.

The layout and functionality of the power amplifier 700 is described with reference to the power amplifier 100 shown at FIGS. 2 and 3. However, with the example power amplifier 700 shown at FIGS. 7 and 8, the fixed harmonic trap 202 of the power amplifier 100 at FIGS. 2 and 3 is deleted in favor of the varactor tuned input trap 702 (i.e., variable harmonic trap). The varactor tuned input trap 702 is an adjustable frequency resonant circuit configured to store energy of the signal present at the input of the trap 702 that corresponds to the center frequency and/or a harmonic of the resonant frequency of the trap 702. In an example, the varactor tuned input trap 702 comprises a (series) LC tank circuit with an adjustable capacitance. As shown at FIG. 7, the varactor tuned input trap 702 includes the varactor 402 (i.e., variable capacitance) and an inductor L1, and has an adjustable resonant frequency as discussed above. The resonant frequency of the varactor tuned input trap 702 is set or adjusted by adjusting the voltage value of the control voltage VCTRL, which is an adjustable voltage source. The control voltage VCTRL is inserted at the node “n” between the cathodes of the two diodes D1 and D2 (see FIG. 4 for more detail) of the varactor 402.

The varactor tuned input trap 702 can be adjusted to have a resonant frequency corresponding to the frequency of the signal to be amplified by the power amplifier 700 and/or transmitted by the transmitter (i.e., a desired transmission signal frequency). This is performed by applying a control voltage VCTRL with a voltage value that causes the varactor 402 to have a desired capacitance. The desired capacitance, in combination with the inductance L1 causes the varactor tuned input trap 702 circuit to attain the desired resonant frequency (corresponding to the frequency of the desired transmission signal, for example). The low impedance varactor tuned input trap 702 circuit can boost the efficiency of the amplifier 700 and optimize the linear gain and phase characteristics (as shown at FIG. 6) by correlating to the frequency of the desired transmission signal, including changing with changes to the frequency of the desired transmission signal.

When it is desirable to amplify and transmit a signal at a different frequency, the varactor tuned input trap 702 can be adjusted to a resonant frequency corresponding to the new frequency. This is performed by adjusting the control voltage VCTRL to a voltage value that causes the varactor 402 to have a different capacitance corresponding to the new resonant frequency. For example, the different capacitance, in combination with the inductance L1, causes the varactor tuned input trap 702 circuit to attain the new resonant frequency. The adjustability of the varactor tuned input trap 702 provides optimized efficiency, gain, and phase performance to the power amplifier 700 while preserving broad-band capability. In other words, since the resonant frequency of the input trap 702 is adjustable, the AMPM can be optimized for each frequency of interest without trading performance at the band edges.

In the examples of FIGS. 7 and 8, the varactor tuned input trap 702 is shown to be implemented interstage between the output of the first transistor stage Q1 and the input of the next transistor stage Q2. Referring to FIGS. 4 and 7, the varactor 402 is coupled in series with the inductance L1. The input of the varactor 402 can be coupled to the input (base) of Q2 and the output of the varactor 402 can be coupled to the inductance L1. The opposite end of the inductance L1 is coupled to ground. As shown at FIG. 7, a capacitance C2 can be disposed between the input of the varactor 402 and the base of the transistor Q2. In alternate variations, additional capacitances, resistances, and inductances may be used, with or without switching, with the varactor 402 to determine the available capacitance values of the varactor 402 or the available resonant frequencies of the varactor tuned input trap 702 (See FIGS. 9A and 9B for examples). In other implementations, the varactor tuned input trap 702 may be coupled to the power amplifier 700 at another location within the amplifier circuit.

As shown at FIGS. 7 and 8, the adjustment control for the example varactor tuned input trap 702 can comprise an adjustable control voltage VCTRL supplied to the node “n” of the varactor 402. As shown at FIG. 8, the control voltage VCTRL can be formed using an adjustable control current IAMPM. In an example, the capacitance of the varactor 402 is the highest (and the resonant frequency of the varactor tuned input trap 702 is the lowest) when the control current IAMPM is at 0 uA. When the control current IAMPM is at a maximum value (e.g., at 1000 uA), the capacitance of the varactor 402 is the lowest (and the resonant frequency of the varactor tuned input trap 702 is the highest). The actual value of the resonant frequency depends on the capacitance of the varactor 402 and the inductance of L1, according to the relationship where the resonant frequency is equal to the reciprocal of 2π multiplied by the square-root of the product of the values of the capacitance of the varactor 402 (in Farads) and the inductance of L1 (in Henries). While the examples disclosed herein describe a variable capacitance varactor 402, the varactor tuned input trap 702 may alternately or additionally include a variable inductance L1. Also, the variable capacitance of the varactor 402 may include additional sets of diodes and/or additional fixed capacitors (in series and/or in parallel with the diodes D1 and D2) in some examples.

FIGS. 9A and 9B show additional examples of variable capacitance circuits that can be utilized as the varactor 402 in the example varactor tuned input trap 702 of FIGS. 7 and 8. In each of the examples of FIGS. 9A and 9B, the respective variable capacitance circuit (902 and 904) is shown to be implemented between input and output nodes. Referring to FIG. 7, the input node can be coupled to the input (base) of Q2, and the output node can be coupled to the output of Q1 (and any LC filter or T-circuit, if present). Alternately, the variable capacitances 902 and 904 can be coupled to the varactor tuned input trap 702 at another location.

FIG. 9A shows that in some embodiments, a variable capacitance circuit 902 can include a plurality of capacitances arranged to be electrically parallel between the input and output nodes, with at least one of such capacitances being switchable to provide a plurality of overall capacitance values between the input and output nodes. For example, in FIG. 9A, three capacitances Ca, Cb, Cc are shown to be arranged to be electrically parallel between the input and output nodes. A switch Sb is shown to be in series with the capacitance Cb, and a switch Sc is shown to be in series with the capacitance Cc. Thus, the overall capacitance values between the input and output nodes can include those associated with Ca alone (each of Sb and Sc open), Ca and Cb in parallel (Sb closed, Sc open), Ca and Cc parallel (Sb open, Sc closed), and all of Ca, Cb and Cc in parallel (each of Sb and Sc closed).

In the example variable capacitance circuit 902 of FIG. 9A, a control signal (not shown) can be provided to control the two example switches Sb, Sc, to thereby control the overall capacitance between the input and output nodes. More particularly, in the example variable capacitance circuit 902, the value of the overall capacitance increases as the switches close by providing respective parallel path(s). Thus, the control signal can be configured to increase or decrease the overall capacitance based on the desired resonance frequency for the varactor tuned input trap 702.

It is noted that the variable capacitance circuit 902 of FIG. 9A is an example where a number of capacitance values can be provided in discrete steps. The number of such capacitance values and the discrete step sizes can be provided by an appropriate choice of the number of switchable capacitances and the values of the capacitances. For example, in the example of FIG. 9A, the two switches (Sb, Sc) are shown to provide four capacitance states. Additional capacitance states for the circuit 902 can be obtained by adding additional switched capacitances (in parallel as shown or in series with one or more of the capacitances).

In some embodiments, the variable capacitance circuit 902 of FIG. 9A can be implemented on the same die as the corresponding switches or on a separate die from the switches. In some embodiments, the variable capacitance circuit 902 of FIG. 9A can be implemented on the same die as the corresponding power amplifier. In some embodiments, the variable capacitance circuit 902 of FIG. 9A can be implemented on a die separate from a die with the corresponding power amplifier.

FIG. 9B shows an example of a variable capacitance circuit 904 that can be configured to provide a diode-based capacitance to provide an analog control of an overall capacitance between input and output nodes, thereby allowing analog control of capacitance of the varactor 904 and of the resonant frequency of the corresponding varactor tuned input trap 702.

For example, referring to FIG. 9B, diodes Da and Db can be provided between the input and output nodes (IN and OUT, respectively), with the anode of the diode Da being on the input side, the anode of the diode Db being on the output side, and the cathodes of the diodes Da, Db being coupled to each other. A capacitance Ca is shown to be between the anode of the diode Da and the input node, and a capacitance Cb is shown to be between the anode of the diode Db and the output node. One resistance Rbig is shown to couple a node between the diode Da and the capacitance Ca to ground, and another resistance Rbig is shown to couple a node between the diode Db and the capacitance Cb to ground. The values of the resistances Rbig may be the same.

In the example of FIG. 9B, a control voltage (VCTRL) is shown to be provided to a node “n” between the cathodes of the diodes Da, Db through a resistance Rbig to control the capacitance being provided by the diodes Da, Db. More particularly, in the example configuration of FIG. 9B, the value of the capacitance provided by the diodes Da, Db decreases as the control voltage VCTRL increases. Thus, a control signal in the form of VCTRL can be configured to increase or decrease the capacitance of the variable capacitance 904 based on an overall capacitance desired.

In some embodiments, the diode-based capacitance 904 in the example of FIG. 9B can be implemented utilizing, for example, an HBT process. In some embodiments, such diode devices can be implemented as transistor devices with capacitance(s) (e.g., Ca and/or Cb) being inherent with the transistor devices. In some embodiments, the variable capacitance circuit 904 of FIG. 9B can be implemented on the same die as the corresponding power amplifier (e.g., HBT power amplifier). In some embodiments, the variable capacitance circuit 904 of FIG. 9B can be implemented on a die separate from a die with the corresponding power amplifier.

One can see that a power amplifier having one or more features as described herein can have very little or virtually zero gain variation over a wide range of control voltages, thereby reducing calibration time and/or demand for power from a transceiver to obtain a desired output power.

It will be understood that in some embodiments, one or more features of the present disclosure can also be implemented in other types of amplifiers other than power amplifiers.

It will also be understood that while various examples are described in the context of amplifying transistors being implemented as bipolar-junction transistors, one or more features of the present disclosure can also be implemented in amplifiers utilizing other types of amplifying transistors.

It will also be understood that while the second stage of the amplifier is described as having a cascode configuration, one or more features of the present disclosure can also be implemented in amplifiers utilizing a non-cascode configuration for a second stage.

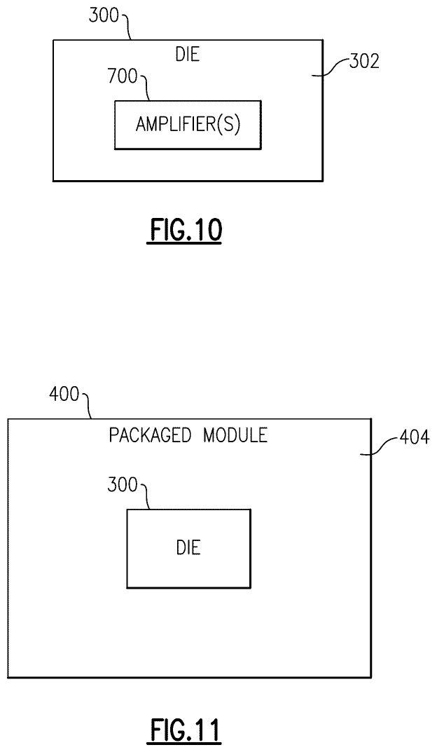

FIG. 10 shows that in some embodiments, a semiconductor die 300 can include one or more amplifiers 700 as described herein, including varactor tuned input trap(s) 702. Such amplifier(s) can be implemented on a semiconductor substrate 302.

FIG. 11 shows that in some embodiments, one or more features as described herein can be implemented in a packaged module 400. Such a packaged module can include a packaging substrate 404 configured to receive a plurality of components. At least some of the components mounted on the packaging substrate 404 can include a die 300 such as one or more of the example die 300 of FIG. 10.

In some implementations, a device and/or a circuit having one or more features described herein can be included in an RF device such as a wireless device. Such a device and/or a circuit can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, etc.

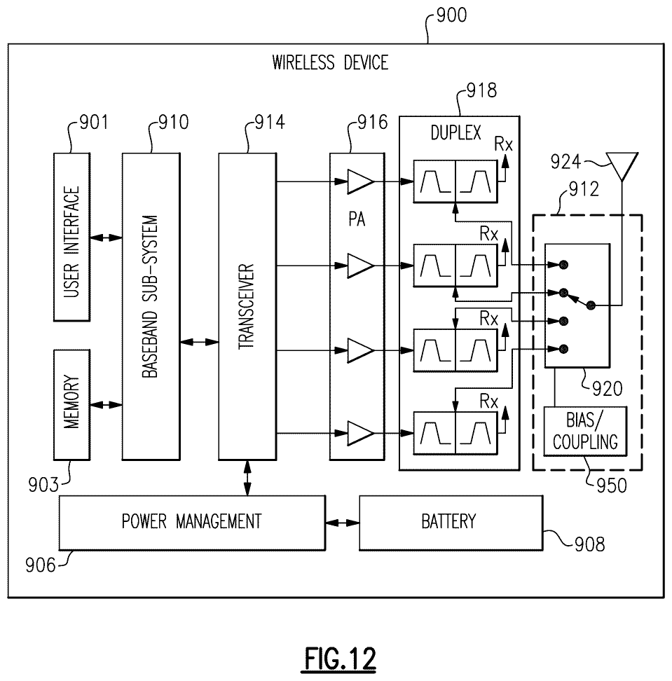

FIG. 12 depicts an example wireless device 900 having one or more advantageous features described herein. In some embodiments, one or more power amplifiers 916 can be functionally equivalent (and may be structurally equivalent) to the power amplifier 700 described herein, including a variable-tuned harmonic trap circuit 702 as described herein.

In the example wireless device 900, a power amplifier (PA) assembly 916 having a plurality of PAs can provide one or more amplified RF signals to the switch 920 (via an assembly of one or more duplexers 918), and the switch 920 can route the amplified RF signal(s) to one or more antennas 924. The PAs 916 can receive corresponding unamplified RF signal(s) from a transceiver 914 that can be configured and operated in known manners. The transceiver 914 can also be configured to process received signals. The transceiver 914 is shown to interact with a baseband sub-system 910 that is configured to provide conversion between data and/or voice signals suitable for a user and RF signals suitable for the transceiver 914. The transceiver 914 is also shown to be connected to a power management component 906 that is configured to manage power for the operation of the wireless device 900. Such a power management component can also control operations of the baseband sub-system 910 and the module 910.

The baseband sub-system 910 is shown to be connected to a user interface 901 to facilitate various input and output of voice and/or data provided to and received from the user. The baseband sub-system 910 can also be connected to a memory 903 that is configured to store data and/or instructions to facilitate the operation of the wireless device 900, and/or to provide storage of information for the user.

In some embodiments, the duplexers 918 can allow transmit and receive operations to be performed simultaneously using a common antenna (e.g., 924). In FIG. 12, received signals are shown to be routed to “Rx” paths that can include, for example, one or more low-noise amplifiers (LNAs).

A number of other wireless device configurations can utilize one or more features described herein. For example, a wireless device does not need to be a multi-band device. In another example, a wireless device can include additional antennas such as a diversity antenna, and additional connectivity features such as Wi-Fi, Bluetooth, and GPS.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A power amplifier comprising:
an input stage that includes a first amplifying transistor having an input node and an output node, such that a signal at the input node has a first power level and an amplified signal at the output node has a second power level;
a second stage implemented relative to the output node that includes a second amplifying transistor; and
an adjustable frequency resonant circuit implemented relative to an input of the second stage, configured to store energy of the amplified signal at the second power level.

2. The power amplifier of claim 1 wherein the adjustable frequency resonant circuit comprises a series LC tank circuit with an adjustable capacitance for tuning a resonant frequency of the series LC tank circuit.

3. The power amplifier of claim 2 further comprising an adjustable control voltage configured to set or adjust the adjustable capacitance of the series LC tank circuit.

4. The power amplifier of claim 1 wherein the adjustable frequency resonant circuit is configured to store energy of the amplified signal relative to a resonant frequency of the adjustable frequency resonant circuit, and wherein the resonant frequency corresponds to a desired transmission signal frequency.

5. The power amplifier of claim 4 wherein the resonant frequency is adjustable in response to a change in the desired transmission signal frequency.

6. The power amplifier of claim 1 wherein the adjustable frequency resonant circuit comprises a varactor in series with an inductance.

7. The power amplifier of claim 6 wherein the adjustable frequency resonant circuit comprises a harmonic trap with an adjustable resonant frequency.

8. The power amplifier of claim 6 wherein a resonant frequency of the adjustable frequency resonant circuit is adjusted by adjusting a capacitance of the varactor.

9. The power amplifier of claim 8 wherein the capacitance of the varactor is controlled via an adjustable control voltage or an adjustable control current.

10. The power amplifier of claim 9 wherein a value of the adjustable control voltage or a value of the adjustable control current is adjusted in response to a change in a desired transmission signal frequency.

11. The power amplifier of claim 6 wherein the varactor comprises two reverse-biased Schottky diodes arranged cathode to cathode, with a control voltage inserted at a node between the cathodes, the control voltage arranged to set or adjust a capacitance of the varactor.

12. The power amplifier of claim 11 wherein the varactor further comprises a capacitance electrically coupled in parallel with the two reverse-biased Schottky diodes.

13. The power amplifier of claim 11 wherein the varactor further comprises a resistance electrically coupled in parallel with the two reverse-biased Schottky diodes.

14. (canceled)

15. (canceled)

16. (canceled)

17. (canceled)

18. (canceled)

19. (canceled)

20. (canceled)

21. (canceled)

22. The power amplifier of claim 1 wherein the adjustable frequency resonant circuit includes a diode capacitance circuit controlled by a control signal that depends on the desired resonance frequency.

23. (canceled)

24. (canceled)

25. The power amplifier of claim 1 wherein the adjustable frequency resonant circuit includes a first diode and a second diode arranged such that an anode of the first diode is on an input side of the variable capacitance circuit, and anode of the second diode is on an output side of the variable capacitance circuit, and cathodes of the first and second diodes are coupled to each other, and a control voltage being provided to a node between the cathodes of the first and second diodes.

26. (canceled)

27. (canceled)

28. (canceled)

29. (canceled)

30. A packaged module comprising:
a packaging substrate; and
a semiconductor die mounted on the packaging substrate and including a power amplifier, the power amplifier including an input stage that includes an amplifying transistor having an input node and an output node, such that a signal at the input node has a first power level and an amplified signal at the output node has a second power level, the power amplifier further including a second stage implemented relative to the output node that includes a second amplifying transistor, the power amplifier further including an adjustable frequency resonant circuit implemented relative to an input of the second stage, configured to store energy of the amplified signal at the second power level.

31. A wireless device comprising:
an antenna configured to receive a signal;
an amplifier assembly in communication with the antenna and configured to amplify the signal, the amplifier assembly including a power amplifier, including an input stage that includes an amplifying transistor having an input node and an output node, such that a signal at the input node has a first power level and an amplified signal at the output node has a second power level and a second stage implemented relative to the output node that includes a second amplifying transistor, and further including an adjustable frequency resonant circuit implemented relative to an input of the second stage, configured to store energy of the amplified signal at the second power level; and
a transceiver in communication with the amplifier assembly and configured to process the amplified signal.

32. The wireless device of claim 31 wherein the wireless device is a cellular phone configured to operate in one or more cellular bands.

33. The wireless device of claim 31 wherein the adjustable frequency resonant circuit is configured to store energy of the amplified signal relative to a resonant frequency of the adjustable frequency resonant circuit.

34. (canceled)

35. The wireless device of claim 31 wherein the adjustable frequency resonant circuit comprises a varactor and an inductance and wherein a resonant frequency of the adjustable frequency resonant circuit is adjusted by adjusting a capacitance of the varactor.
